(19) United States
(12) Patent Application Publication
(10) Pub. No.: US 2010/0314696 A1
(43) Pub. Date: Dec. 16, 2010

(54) FIELD-EFFECT TRANSISTOR AND METHOD OF FABRICATING SAME

(75) Inventors: Akihiko NISHIO, Toyama (JP); Akiyoshi TAMURA, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/722,583

(22) Filed: Mar. 12, 2010

(30) Foreign Application Priority Data
Jun. 10, 2009 (JP) 2009-139676

(51) Int. Cl. H01L 29/78; H01L 21/336

(52) U.S. Cl. 257/411; 438/287; 257/E29.255; 257/E21.409

(57) ABSTRACT

A field-effect transistor having a high-quality semiconductor/oxide interface and a method of fabricating the field-effect transistor are provided. The field-effect transistor includes a semiconductor substrate; a channel layer formed on the semiconductor substrate; a donor layer formed on the channel layer; a semiconductor layer formed in the donor layer and containing Pt; an oxide layer formed on the semiconductor layer and containing a perovskite-type oxide which functions as a gate insulating film; and a gate electrode formed on the oxide layer.

### BACKGROUND OF THE INVENTION

(1) Field of the Invention

The present invention relates to field-effect transistors and methods of fabricating the same, and particularly to metal oxide semiconductor (MOS) field-effect transistors.

(2) Description of the Related Art

In recent years, field-effect transistors (hereinafter referred to as FETs) having compound semiconductors such as GaAs have been widely used for radio communication, in particular, as power amplifiers, radio frequency (RF) switches, and other components in cellular phone units. Among these FETs, especially pseudomorphic high electron mobility transistors (PHEMTs) exhibit good radio frequency characteristics. Furthermore, the PHEMTs have been widely applied to semiconductor devices such as the monolithic microwave integrated circuits (MMIC) on which active elements such as the FETs are integrated with passive elements such as semiconductor resistors, metal resistors, and capacitors.

The field-effect transistors are typically required to reduce leakage current, and it is predicted that the demand for reduction of leakage current will be high, especially on the PHEMTs, which are applied to the MMICs, along with development of the radio frequency technology. The PHEMTs, which are field-effect transistors using the Schottky junction, involve a problem of a large leakage current compared to metal-insulator-semiconductor (MIS) field-effect transistors.

To address this problem, using a GaAs substrate to form the metal-oxide-semiconductor (MOS) structure, which generally uses a Si substrate, has been attempted for several decades, but not yet been put to practical use. Meanwhile, the MOS structure using a Si substrate has been technically developed by changing a material of an oxide from a natural oxide film to a material with a higher permittivity. In particular, a perovskite-type oxide draws attention as a high-permittivity material which is good as a gate oxide (see Patent Reference 1: Japanese Unexamined Patent Application Publication No. 6-314794).

In the case of using the perovskite-type oxide as a gate oxide, the perovskite-type oxide is desirably formed with a uniform crystallographic orientation, as disclosed in Patent Reference 1. It is known that strontium titanate (SrTiO₃), which is one example of the perovskite-type oxide, is more likely to have a uniform crystallographic orientation when formed on Si.

However, the perovskite-type oxide includes lead lanthanum zirconate titanate (PZLT) and the like, of which crystallographic orientation will not be uniform when formed on Si. Patent reference 1 solves this problem by forming, on top of the Si, SrTiO₃ with a uniform crystallographic orientation and then forming PZLT thereon.

### SUMMARY OF THE INVENTION

The above related art, however, has a problem that it is difficult to form a high-quality semiconductor/oxide interface because materials usable for a semiconductor substrate and a gate oxide film are limited.

In the technique disclosed by Patent Reference 1, PZLT with a uniform crystallographic orientation cannot be formed directly on Si, for example.

On the other hand, on top of a group III-V compound semiconductor made of GaAs or the like, crystallographic orientations of the perovskite-type oxide cannot be uniform. It is thus difficult to form a MOS structure using the perovskite-type oxide.

In view of this, the present invention has been conceived to solve the above problem, and an object of the present invention is to provide a field-effect transistor having a high-quality semiconductor/oxide interface and a method of fabricating the field-effect transistor.

In order to achieve the above object, the field-effect transistor according to the present invention includes: a semiconductor substrate; a channel layer formed on the semiconductor substrate; a donor layer formed on the channel layer; a semiconductor layer formed in the donor layer and containing Pt; an oxide layer formed on the semiconductor layer and containing a perovskite-type oxide which functions as a gate insulating film; and a gate electrode formed on the oxide layer.

This enables the perovskite-type oxide with a uniform crystallographic orientation to be deposited on Pt, with the result that the field-effect transistor according to the present invention has a high-quality semiconductor/oxide interface. Leakage current can be therefore reduced more than, for example, conventional MIS field-effect transistors.

Furthermore, the field-effect transistor may further include: ohmic contact layers formed on the donor layer so that the gate electrode is located between the ohmic contact layers; insulating films formed on the donor layer and the ohmic contact layers and including a first opening and second openings, the first opening being located in a region on the donor layer and the second openings each being located in a region on a corresponding one of the ohmic contact layers; and ohmic electrodes each of which is in electrical contact with a corresponding one of the ohmic contact layers via a corresponding one of the second openings, wherein the semiconductor layer is formed on the donor layer so as to be exposed to the first opening, and the oxide layer is formed in the first opening.

Furthermore, the field-effect transistor may further include Pt layers each formed between the oxide layer and a corresponding one of the insulating films.

Furthermore, the semiconductor substrate may be a group III-V compound semiconductor substrate

Furthermore, the semiconductor substrate may be a substrate which contains GaAs, InP, or GaN.

Since a group III-V compound semiconductor made of GaAs, InP, GaN, or the like has good radio frequency characteristics, it can be used as a high speed semiconductor device.

Furthermore, the oxide layer may contain SrTiO₃.

Since SrTiO₃ is an oxide which is characterized by having a high permittivity and is useful as a gate oxide, the field-effect transistor according to the present invention is low in leakage current, provides superior radio frequency response properties, and is capable of operating at high speed.

Furthermore, the semiconductor layer may further contain atoms of a material included in the donor layer.

Furthermore, the gate electrode may contain a material having low leakage current into the perovskite-type oxide.

This can lead to reduction in leakage current from the gate electrode to the oxide layer.

For example, the material contained in the gate electrode may be Pt, WSi, or WSiN.

Furthermore, the method of fabricating a field-effect transistor according to the present invention may include: forming a channel layer on a semiconductor substrate; forming a donor layer on the channel layer; forming a Pt layer on the donor layer, the Pt layer being a layer containing Pt; forming an oxide layer on the Pt layer, the oxide layer containing a perovskite-type oxide which functions as a gate insulating film; forming a semiconductor layer by diffusing Pt contained in the Pt layer into the donor layer through thermal treatment; and forming a gate electrode on the oxide layer.

This enables a high-quality perovskite-type oxide with a uniform crystallographic orientation to be formed on the Pt layer, and also enables forming a semiconductor layer by diffusing Pt contained in the Pt layer into the donor layer through thermal treatment. Consequently, the field-effect transistor according to the present invention is low in leakage current, provides superior radio frequency response properties, and is capable of operating at high speed.

Furthermore, in the forming of a Pt layer, the Pt layer may be formed to be 2 nm or less in thickness.

This enables, for example, the perovskite-type oxide with a uniform crystallographic orientation to be deposited on Pt, with the result that a higher-quality semiconductor/oxide interface can be formed.

Furthermore, the method of fabricating a field-effect transistor may further include: forming ohmic contact layers in regions except a predetermined region on the donor layer; forming insulating films on the predetermined region of the donor layer and on the ohmic contact layers, and forming a first opening in a region on the donor layer and second openings each in a region on a corresponding one of the ohmic contact layers; and forming ohmic electrodes each of which is in electrical contact with a corresponding one of the ohmic contact layers via a corresponding one of the second openings, wherein in the forming of a Pt layer, the Pt layer is formed in a region which is located on the donor layer and exposed on the first opening, and in the forming of an oxide layer, the oxide layer is formed on the Pt layer formed in the first opening.

According to the present invention, it is possible to provide a field-effect transistor having a high-quality semiconductor/oxide interface and a method of fabricating the field-effect transistor.

### FURTHER INFORMATION ABOUT TECHNICAL BACKGROUND TO THIS APPLICATION

The disclosure of Japanese Patent Application No. 2009-139676 filed on Jun. 10, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view showing one example of a structure of a field-effect transistor according to a first embodiment;

FIG. 2 is a cross-sectional view showing one example of a process of fabricating the field-effect transistor according to the first embodiment;

FIG. 3 is a cross-sectional view showing one example of a structure of a field-effect transistor according to a second embodiment; and

FIG. 4 is a cross-sectional view showing one example of a process of fabricating the field-effect transistor according to the second embodiment.

### DESCRIPTION OF THE PREFERRED EMBODIMENTS

Referring to the drawings, the field-effect transistors and the methods of fabricating the same according to the present invention will be illustrated below by embodiments.

### First Embodiment

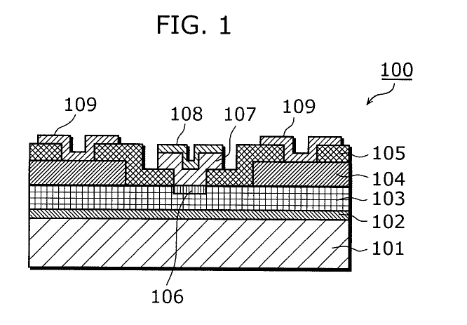

The field-effect transistor according to the present invention includes a channel layer, a donor layer, a semiconductor layer formed in the donor layer, an oxide layer, and a gate electrode. To be specific, the oxide layer is made by forming a perovskite-type oxide on a Pt layer from which Pt is diffused into the donor layer through thermal treatment to form the semiconductor layer. Firstly, one example of a structure of the field-effect transistor according to the present embodiment will be described below with reference to FIG. 1.

FIG. 1 is a cross-sectional view showing one example of a structure of a field-effect transistor 100 according to the present embodiment. The field-effect transistor 100 shown in FIG. 1 is a MOS field-effect transistor, including a semiconductor substrate 101, a channel layer 102, a donor layer 103, an ohmic contact layer 104, an insulating film 105, a semiconductor layer 106, a perovskite-type oxide layer 107, a gate electrode 108, and an ohmic electrode 109.

The semiconductor substrate 101 is a group III-V compound semiconductor substrate and, for example, is a semi-insulating GaAs substrate. The semiconductor substrate 101 may be another group III-V compound semiconductor substrate made of InP, GaN, or the like, and may alternatively be a group II-VI compound semiconductor substrate or a group IV semiconductor substrate made of Si or the like.

The channel layer 102 is a layer formed on the semiconductor substrate 101 by combining semiconductors having different band gaps, and contains two-dimensional electron gas. The channel layer 102 is made of, for example, 5 nm-thick InGaAs. Between the semiconductor substrate 101 and the channel layer 102, a buffer layer (not shown) is formed to reduce lattice mismatch. The buffer layer is made of AlGaAs, for example.

The donor layer 103 is formed on the channel layer 102 and donates thereto electrons, which serve as carriers. The donor layer 103 is made of, for example, 20 nm-thick AlGaAs. It is to be noted that the donor layer 103 is not limited to a single-layer structure of AlGaAs and may have a laminate structure of AlGaAs, GaAs, InGaP, and so on. In addition, the thickness of the donor layer 103 may change according to a FET threshold voltage.

The ohmic contact layer 104 is formed on the donor layer 103 and divided into two regions (a source region and a drain region) by a recessed opening formed in a gate region. The source region and the drain region are connected to ohmic electrodes 109, which are a source electrode and a drain electrode, respectively, of the FET. The ohmic contact layer 104 is made of, for example, GaAs or InGaAs, which is high in electron density, or may have a laminate structure of GaAs and InGaAs. The ohmic contact layer 104 has a thickness of, for example, 50 to 100 nm.

The insulating film 105 provides electrical isolation and is formed on the ohmic contact layer 104 and on the donor layer 103 in the recessed opening formed in the ohmic contact layer 104. In the insulating film 105, the gate region, the source region, and the drain region each have an opening in which an electrode is formed. The insulating film 105 is made of, for example, 200 to 400 nm-thick silicon nitride (SiN) or alternatively may have a laminate structure of SiN and silicon oxide (SiO₂).

The semiconductor layer 106 is a layer formed by diffusing impurities into the donor layer 103, and controls a threshold voltage, a breakdown voltage, and the like, of the MOSFET. For example, the semiconductor layer 106 is formed by diffusing Pt into GaAs of high electron density of which the donor layer 103 is made. This results in the semiconductor layer 106 which contains Pt and atoms (Ga and As) of the material of which the donor layer 103 is made.

The perovskite-type oxide layer 107 is an FET gate insulating film formed on the semiconductor layer 106 and is made of, for example, 30-100 nm-thick SrTiO₃. The perovskite-type oxide layer 107 may be made of another perovskite-type oxide such as PZLT, but in the case of the field-effect transistor intended for radio frequency operation, it is preferable to use a material (such as SrTiO₃) which does not exhibit ferroelectricity.

The gate electrode 108 is an electrode formed on the perovskite-type oxide layer 107, and is preferably made of a material having low leakage current into the perovskite-type oxide layer 107. For example, the gate electrode 108 is made of Pt, WSi, or WSiN.

The ohmic electrode 109 is an FET source or drain electrode formed on the ohmic contact layer 104. For example, the ohmic electrode 109 has a laminate structure of Ti, Al or Pt, Au, and so on. In this case, Ti is used to reduce the contact resistance to the ohmic contact layer 104, and Al or Pt, Au, and so on are used to lower the resistance.

As described above, in the field-effect transistor 100 of FIG. 1, the semiconductor layer 106 is present in the donor layer 103 and located just under the perovskite-type oxide layer 107, and a MOS structure is thus formed of the semiconductor layer 106, the perovskite-type oxide layer 107, and the gate electrode 108.

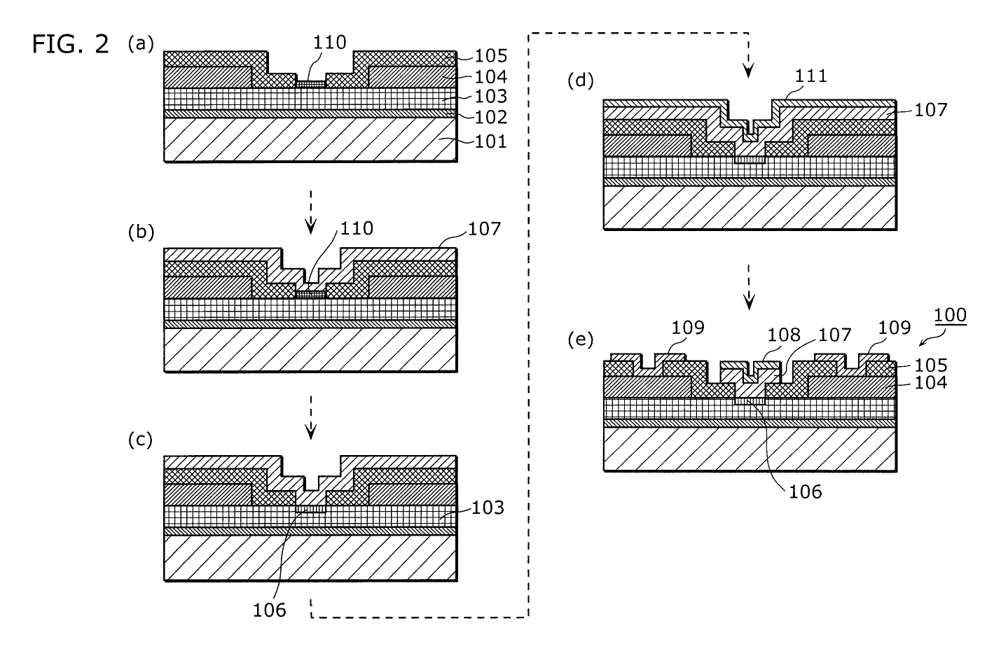

Next, referring to FIG. 2, one example of the method of fabricating the field-effect transistor 100 according to the present embodiment will be explained. FIG. 2 is a cross-sectional view showing one example of the method of fabricating the field-effect transistor 100 according to the present embodiment.

Firstly, as shown in FIG. 2(a), on top of the semiconductor substrate 101 such as a semi-insulating GaAs substrate, the buffer layer (not shown), the channel layer 102 made of InGaAs, the donor layer 103 made of AlGaAs, and the ohmic contact layer 104 made of GaAs or the like, are deposited, for example. Next, patterning is performed by photolithography using a photoresist followed by dry etching or wet etching to remove a gate region of the ohmic contact layer 104 and thereby form a recessed opening such that the donor layer 103 is exposed.

Subsequently, the insulating film 105 made of SiN is deposited on the entire surface by plasma CVD (chemical vapor deposition). The patterning is then performed by the photolithography followed by dry etching or wet etching to remove a predetermined region of the insulating film 105 and thereby form a gate electrode region where the donor layer 103 is exposed.

Next, Pt is deposited selectively in the gate electrode region by patterning using photolithography and then vapor deposition and lift-off, thus resulting in a Pt layer 110. This Pt layer 110 desirably has a thickness of 2 nm or less.

Next, as shown in FIG. 2(b), the perovskite-type oxide such as SrTiO₃ is deposited on the entire surface by the RF sputtering, MOCVD, or sol-gel process, resulting in the perovskite-type oxide layer 107. At this time, a perovskite-type oxide formed on the Pt layer 110 has uniform crystallinity.

Next, a thermal treatment is performed in an oxygen atmosphere at 350° C. or higher temperature. At this time, Pt is diffused into the donor layer 103, resulting in a new semiconductor layer 106 as shown in FIG. 2(c).

Subsequently, as shown in FIG. 2(d), a gate electrode material 111, which results in a gate electrode metal, is deposited on the perovskite-type oxide layer 107 by the sputtering process. The gate electrode material 111 needs to be made of a material having low leakage current into the perovskite-type oxide, and is preferably made of Pt, WSi, or WSiN.

Next, as shown in FIG. 2(e), the gate electrode material 111 and the perovskite-type oxide layer 107 are patterned using photolithography and then etched by dry etching. This results in the MOS structure of the gate electrode 108, the perovskite-type oxide layer 107, and the semiconductor layer 106. The patterning using photolithography is further performed followed by dry etching or wet etching to form a source electrode region and a drain electrode region on each of which the ohmic contact layer 104 is exposed.

After that, an ohmic electrode material is deposited by the sputtering or vapor deposition process and then, patterned and etched to form the ohmic electrodes 109, which serve as a source electrode and a drain electrode. The ohmic electrode material typically has a laminate structure of Ti, which is used to come into contact with the ohmic contact layer 104, and Al or Pt, Au, and so on, which are used to lower the resistance.

Through the above fabricating process, the MOS field-effect transistor having a group III-V compound semiconductor, as shown in FIG. 1, can be formed.

As above, the field-effect transistor 100 according to the present embodiment is an MOS field-effect transistor formed by taking advantage of such a property of the perovskite-type oxide that its crystallinity will be uniform when accumulating on Pt, and furthermore of such a property of Pt that at around 350° C. or higher temperature, Pt is thermally diffused into a group III-V compound semiconductor such as GaAs, which results in a semiconductor layer. In sum, as described above, the field-effect transistor 100 according to the present embodiment includes the perovskite-type oxide layer 107 as a gate insulating film, and further includes the semiconductor layer 106 that is formed by diffusing Pt into the donor layer 103.

With such a high-quality semiconductor/oxide interface, the field-effect transistor 100 according to the present embodiment is low in leakage current, provides superior radio frequency response properties, and is capable of operating at high speed.

### Second Embodiment

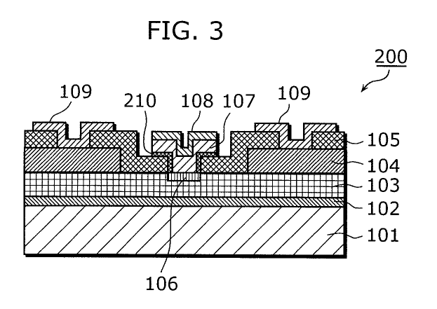

While the Pt layer is selectively formed in the region just under the gate electrode in the first embodiment, a field-effect transistor according to the present embodiment has a Pt layer on an entire surface. Accordingly, the field-effect transistor according to the present embodiment additionally includes a Pt layer in an interface between the oxide layer and the insulating film as compared to the field-effect transistor according to the first embodiment. The following shall firstly describe one example of a structure of the field-effect transistor according to the present embodiment with reference to FIG. 3.

FIG. 3 is a cross-sectional view showing one example of the structure of a field-effect transistor 200 according to the present embodiment. The field-effect transistor 200 shown in FIG. 3 is different from the field-effect transistor 100 according to the first embodiment in that a Pt layer 210 is additionally provided. Hereinbelow, the same configurations as those in the first embodiment will be denoted by the same reference numerals and explanation thereof will be omitted to focus on differences.

The Pt layer 210 is a Pt layer formed in the interface which is between the insulating film 105 and the perovskite-type oxide layer 107 and located in a region where the gate electrode 108 is formed. The Pt layer 210 has a thickness of, for example, 2 nm or less.

As described above, in the field-effect transistor 200 of FIG. 3, the semiconductor layer 106 is present in the donor layer 103 and located just under the perovskite-type oxide layer 107, and a MOS structure is thus formed of the semiconductor layer 106, the perovskite-type oxide layer 107, and the gate electrode 108. Furthermore, in the present embodiment, the Pt layer 210 is formed on a side wall and a bottom surface of the perovskite-type oxide layer 107 that is a T-shaped gate oxide film, which side wall and bottom surface face the insulating layer 105.

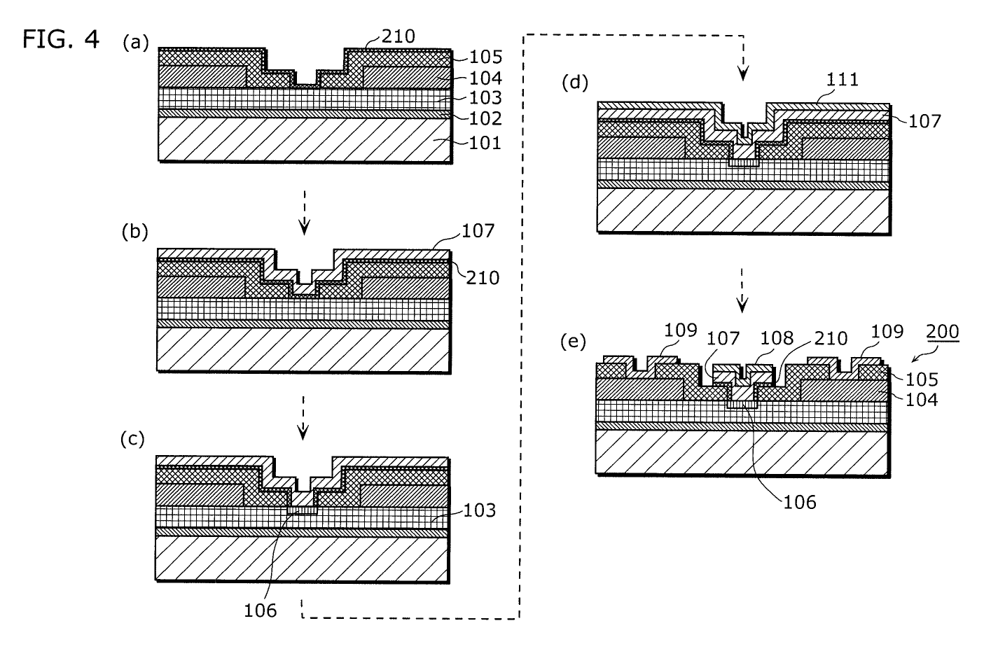

Next, referring to FIG. 4, one example of a method of fabricating the field-effect transistor 200 according to the present embodiment will be explained. FIG. 4 is a cross-sectional view showing one example of the method of fabricating the field-effect transistor 200 according to the present embodiment.

Firstly, as shown in FIG. 4(a), as in the case of the first embodiment, on top of the semiconductor substrate 101, the buffer layer (not shown), the channel layer 102, the donor layer 103, the ohmic contact layer 104, and the insulating film 105 are formed. The ohmic contact layer 104 has a predetermined region (gate region) removed by etching after patterning using photolithography, thereby being divided into two regions (a source region and a drain region). Moreover, the insulating film 105 formed in the gate region has a predetermined region (gate electrode region) removed by etching after patterning using photolithography.

Subsequently, Pt is deposited on the entire surface by the sputtering or vapor deposition process, resulting in the Pt layer 210. This Pt layer 210 desirably has a thickness of 2 nm or less.

Next, as shown in FIG. 4(b), the perovskite-type oxide such as SrTiO₃ is deposited on the entire surface by the RF sputtering, MOCVD, or sol-gel process, resulting in the perovskite-type oxide layer 107. At this time, on top of the Pt layer 210 is formed a perovskite-type oxide with uniform crystallinity. In the present embodiment, since the Pt layer 210 is formed on the entire surface, all the regions are covered with the perovskite-type oxide layer 107 having uniform crystallinity.

Next, a thermal treatment is performed in an oxygen atmosphere at 350° C. or higher temperature. At this time, Pt is diffused into the donor layer 103, resulting in a new semiconductor layer 106 as shown in FIG. 4(c).

Subsequently, as shown in FIG. 4(d), a gate electrode material 111, which results in a gate electrode metal, is deposited on the perovskite-type oxide layer 107 by the sputtering process. The gate electrode material 111 needs to be made of a material having low leakage current into the perovskite-type oxide, and is preferably made of Pt, WSi, or WSiN.

Next, as shown in FIG. 4(e), the gate electrode material 111, the perovskite-type oxide layer 107, and the Pt layer 210 are patterned using photolithography and then etched by dry etching. This results in the MOS structure of the gate electrode 108, the perovskite-type oxide layer 107, and the semiconductor layer 106.

Next, as in the case of the first embodiment, the source electrode region and the drain electrode region of the insulating film 105 are removed so that the ohmic contact layer is exposed. After that, an ohmic electrode material is deposited by the sputtering or vapor deposition process and then, patterned and etched, thereby resulting in the ohmic electrodes 109, which serve as a source electrode and a drain electrode. The ohmic electrode material typically has a laminate structure of Ti, which is used to come into contact with the ohmic contact layer, and Al or Pt, Au, and so on, which are used to lower the resistance.

Through the above fabricating process, the MOS field-effect transistor having a group III-V compound semiconductor, as shown in FIG. 3, can be formed.

As above, the field-effect transistor 200 according to the present embodiment is, as in the case of the first embodiment, an MOS field-effect transistor formed by taking advantage of such a property of the perovskite-type oxide that its crystallinity will be uniform when accumulating on Pt, and furthermore of such a property of Pt that at around 350° C. or higher temperature, Pt is thermally diffused into a group III-V compound semiconductor such as GaAs, which results in a semiconductor layer. In sum, as described above, the field-effect transistor 200 according to the present embodiment includes the perovskite-type oxide layer 107 as a gate insulating film, and further includes the semiconductor layer 106 that is formed by diffusing Pt into the donor layer 103.

In the present embodiment, the perovskite-type oxide is deposited on Pt deposited on the entire surface while in the first embodiment the perovskite-type oxide is deposited on Pt deposited only in the gate electrode region. The deposited perovskite-type oxide in the present embodiment therefore has higher crystallinity. The Pt layer deposited on the entire layer remains in the interface between the perovskite-type oxide layer 107 and the insulating film 105, which interface is in the gate region.

With such a high-quality semiconductor/oxide interface, the field-effect transistor 200 according to the present embodiment is low in leakage current, provides superior radio frequency response properties, and is capable of operating at high speed.

While the field-effect transistor and the method of fabricating the same according to the present invention have been described with reference to the embodiments thereof, the present invention is not limited to these embodiments. The scope of the present invention includes various variation of the embodiments which will occur to those skilled in the art, and other embodiments in which element of different embodiments are combined, without departing from the basic principles of the present invention.

### INDUSTRIAL APPLICABILITY

The field-effect transistor and the method of fabricating the same according to the present invention produce an effect, for example, that the field-effect transistor is capable of operating at high speed with a high-quality semiconductor/oxide interface, and these can be applied to various semiconductor devices such as MMICs, for example.

What is claimed is:

1. A field-effect transistor comprising:
a semiconductor substrate;
a channel layer formed on said semiconductor substrate;
a donor layer formed on said channel layer;
a semiconductor layer formed in said donor layer and containing Pt;
an oxide layer formed on said semiconductor layer and containing a perovskite-type oxide which functions as a gate insulating film; and
a gate electrode formed on said oxide layer.

2. The field-effect transistor according to claim 1, further comprising:
ohmic contact layers formed on said donor layer so that said gate electrode is located between said ohmic contact layers;
insulating films formed on said donor layer and said ohmic contact layers and including a first opening and second openings, said first opening being located in a region on said donor layer and said second openings each being located in a region on a corresponding one of said ohmic contact layers; and
ohmic electrodes each of which is in electrical contact with a corresponding one of said ohmic contact layers via a corresponding one of said second openings,
wherein said semiconductor layer is formed on said donor layer so as to be exposed to said first opening, and
said oxide layer is formed in said first opening.

3. The field-effect transistor according to claim 2, further comprising
Pt layers each formed between said oxide layer and a corresponding one of said insulating films.

4. The field-effect transistor according to claim 1,
wherein said semiconductor substrate is a group III-V compound semiconductor substrate.

5. The field-effect transistor according to claim 4,
wherein said semiconductor substrate is a substrate which contains GaAs, InP, or GaN.

6. The field-effect transistor according to claim 1,
wherein said oxide layer contains SrTiO₃.

7. The field-effect transistor according to claim 1,
wherein said semiconductor layer further contains atoms of a material included in said donor layer.

8. The field-effect transistor according to claim 1,
wherein said gate electrode contains a material having low leakage current into the perovskite-type oxide.

9. The field-effect transistor according to claim 8, wherein the material contained in said gate electrode is Pt, WSi, or WSiN.

10. A method of fabricating a field-effect transistor, comprising:
forming a channel layer on a semiconductor substrate;
forming a donor layer on the channel layer;
forming a Pt layer on the donor layer, the Pt layer being a layer containing Pt;
forming an oxide layer on the Pt layer, the oxide layer containing a perovskite-type oxide which functions as a gate insulating film;
forming a semiconductor layer by diffusing Pt contained in the Pt layer into the donor layer through thermal treatment; and
forming a gate electrode on the oxide layer.

11. The method of fabricating a field-effect transistor according to claim 10,
wherein in said forming of a Pt layer, the Pt layer is formed to be 2 nm or less in thickness.

12. The method of fabricating a field-effect transistor according to claim 11, further comprising:
forming ohmic contact layers in regions except a predetermined region on the donor layer;
forming insulating films on the predetermined region of the donor layer and on the ohmic contact layers, and forming a first opening in a region on the donor layer and second openings each in a region on a corresponding one of the ohmic contact layers; and
forming ohmic electrodes each of which is in electrical contact with a corresponding one of the ohmic contact layers via a corresponding one of the second openings,
wherein in said forming of a Pt layer, the Pt layer is formed in a region which is located on the donor layer and exposed on the first opening, and
in said forming of an oxide layer, the oxide layer is formed on the Pt layer formed in the first opening.
